(19) United States
(12) Patent Application Publication
(10) Pub. No.: US 2017/0186991 A1
(43) Pub. Date: Jun. 29, 2017

(54) LIGHT EMITTING DEVICE AND METHOD FOR MANUFACTURING THE SAME

(71) Applicant: InnoLux Corporation, Miao-Li County (TW)

(72) Inventors: Yixin YANG, Miao-Li County (TW); Fang-Iy WU, Miao-Li County (TW); Cheng-Hsiung LIU, Miao-Li County (TW); Cheng-Hsu CHOU, Miao-Li County (TW)

(21) Appl. No.: 15/381,287

(22) Filed: Dec. 16, 2016

(30) Foreign Application Priority Data
Dec. 24, 2015 (TW) 104143513

(51) Int. Cl. H01L 51/52

(52) U.S. Cl. CPC H01L 51/525; H01L 51/5246; H01L 51/5253; H01L 51/5237

(57) ABSTRACT

A light emitting device and a method for manufacturing the same are disclosed. Herein, the light emitting device comprises: a substrate having a light emitting region and a sealing region surrounding the light emitting region; an OLED unit disposed over the light emitting region; a protection layer disposed over the OLED unit; a support unit disposed over the sealing region, wherein materials of the protection layer and the support unit are the same, and the support unit connects to the protection layer; and a cover disposed over the protection layer and the support unit; wherein a first height is between a surface of the support unit adjacent to the cover and a surface of the substrate, a second height is between a surface of the protection layer adjacent to the cover and the surface of the substrate, and the first height is larger than the second height.

### CROSS REFERENCE TO RELATED APPLICATION

This application claims the benefits of the Taiwan Patent Application Serial Number 104143513, filed on Dec. 24, 2015, the subject matter of which is incorporated herein by reference.

### BACKGROUND

1. Field of the Disclosure

The present disclosure relates to a light emitting device and a method for manufacturing the same. More particularly, the present disclosure relates to a light emitting device having support units with special structures and a method for manufacturing the same.

2. Description of Related Art

Organic light-emitting diodes (OLEDs) are light in weight, ultra-thin in thickness, and have features, such as high brightness, rapid response, wide viewing angles, no backlight requirement, low manufacturing cost, and flexibility. As a result, OLED devices have a great potential to be applied in various light emitting devices, such as display devices, lamps, etc.

However, the surface of OLED units can be uneven or cracked easily by collision or pressing, resulting in poor light emission of OLED devices. For example, during an encapsulation process of an OLED unit, when a cover is to be assembled, since the cover is flexible, the cover may be pressed down onto the surface of the OLED unit to damage the OLED unit. In addition, during the manufacturing process of an OLED unit, although particles that adhered to the surface of the OLED unit are removed as much as possible; however, it is still possible that a trace amount of such particles will remain on the surface of the OLED unit. Consequently, when the cover is pressed down or when the OLED device is bent, the aforesaid particles may be pressed down onto the surface of the OLED unit and damage the OLED unit.

Therefore, there is a need to develop a light emitting device with an OLED unit in which the aforementioned issues are solved.

### SUMMARY

The object of the present disclosure is to provide a light emitting device and a method for manufacturing the same. Specifically, a support unit is disposed in the light emitting device to improve the OLED unit from being damaged. More specifically, the height of the support unit is greater than the height of a protection layer disposed on the OLED unit. The OLED unit could be replaced by an LED unit, ex. a micro LED unit.

The light emitting device of an embodiment of the present disclosure comprises: a substrate comprising a light emitting region and a sealing region surrounding the light emitting region; an OLED unit disposed on the light emitting region; a protection layer disposed over the OLED unit; a support unit disposed over the sealing region, wherein materials of the protection layer and the support unit are the same, and the support unit connects to the protection layer; and a cover disposed over the protection layer and the support unit; wherein a first height is a maximum vertical distance between a surface of the support unit adjacent to the cover and a surface of the substrate, a second height is a maximum vertical distance between a surface of the protection layer adjacent to the cover and the surface of the substrate, and the first height is greater than the second height.

In addition, a method for manufacturing the light emitting device of an embodiment of the present disclosure comprises: providing a substrate comprising a light emitting region and a sealing region surrounding the light emitting region; forming an OLED unit over the light emitting region; coating an adhesive over the OLED unit and the sealing region; curing the adhesive to form a protection layer over the OLED unit and a support unit over the sealing region, wherein a first height is a maximum vertical distance between a surface of the support unit and a surface of the substrate, a second height is a maximum vertical distance between a surface of the protection layer and the surface of the substrate, and the first height is greater than the second height; and disposing a cover over the protection layer and the support unit.

In the light emitting device and the method for manufacturing the same of the present disclosure, the support unit is integrated with the protection layer disposed on the OLED unit. Since the height of the support unit is greater than the height of the protection layer disposed on the OLED unit, a space is formed between the cover and the protection layer. Subsequently, the problem of the damage of the OLED units caused by pressing or compressing can be improved during the process of disposing the cover and in situations of pressing the cover or bending flexible devices. More particularly, the damage of the OLED units caused by the particles adhered to the surface of the OLED units being pressed to touch or press down onto the surface of the OLED units can be prevented. Thereby, the lifetime of devices can be increased or the display quality can be improved.

Other objects, advantages, and novel features of the present disclosure will become more apparent from the following detailed description when taken in conjunction with the accompanying drawings.

### BRIEF DESCRIPTION OF THE DRAWINGS

FIGS. 1A-1D are schematic diagrams showing a manufacturing process of a display device of Embodiment 1 of the present disclosure in cross-sectional view;

FIG. 2 is a cross-sectional view of a display device of Embodiment 2 of the present disclosure;

FIG. 3 is a cross-sectional view of a display device of Embodiment 3 of the present disclosure;

FIGS. 4A-4C are schematic diagrams showing a manufacturing process of a display device of Embodiment 4 of the present disclosure in cross-sectional view; and

FIG. 5 is a cross-sectional view of a display device of Embodiment 5 of the present disclosure.

### DETAILED DESCRIPTION OF THE PREFERRED EMBODIMENT

The present disclosure has been described in an illustrative manner It is to be understood that the terminologies used are intended to be in the nature of description rather than of limitation. Many modifications and variations of the present disclosure are possible in light of the above teachings. Therefore, it is to be understood that within the scope of the appended claims, the disclosure may be practiced otherwise than as specifically described.

Hereinafter, terms such as “first” and “second” in the specification and claims are only intended to make clear distinction of elements with the same name. These terms do not mean these elements are used or manufactured in any sequence.

It should be noted that the elements or devices in the drawings of the present disclosure may be present in any form or configuration known to those skilled in the art. In addition, the expression “a layer overlying another layer”, “a layer is disposed above another layer”, “a layer is disposed on another layer” and “a layer is disposed over another layer” may indicate that the layer is in direct contact with the other layer, or that the layer is not in direct contact with the other layer, there being one or more intermediate layers disposed between the layer and the other layer.

In addition, in this specification, relative expressions are used. For example, “lower”, “bottom”, “higher” or “top” are used to describe the position of one element relative to another. It should be appreciated that if a device is flipped upside down, an element that is “lower” will become an element that is “higher”.

### Embodiment 1

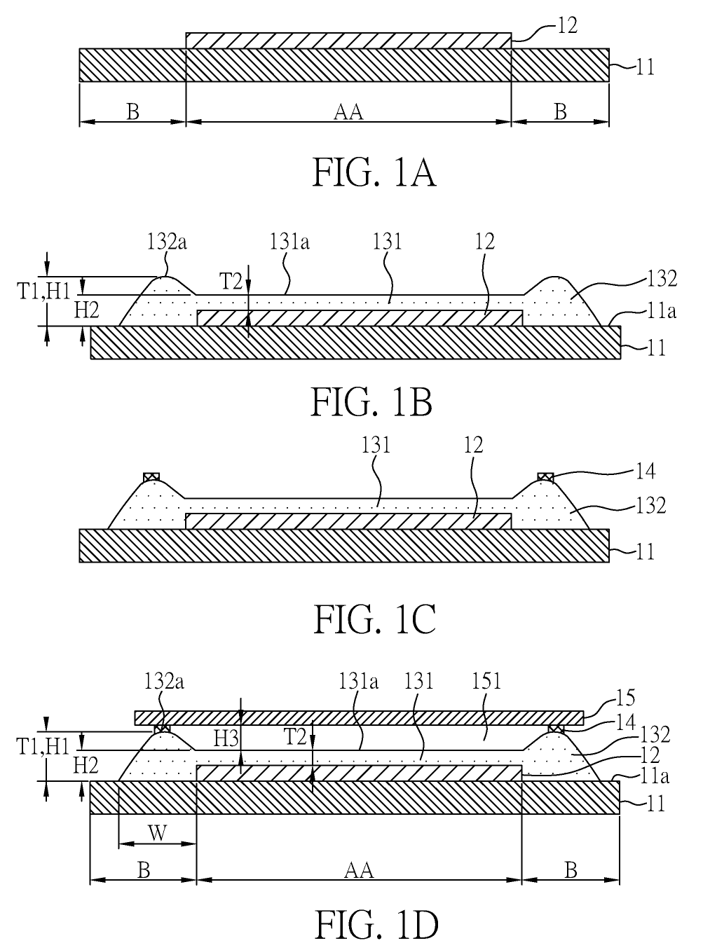

FIGS. 1A to 1D are schematic diagrams showing a manufacturing process of a display device of the present Embodiment in cross-sectional view. As shown in FIG. 1A, a substrate (11) having a light emitting region (AA) and a sealing region (B) surrounding the light emitting region (AA) is provided. In the present Embodiment, the substrate (11) can be made of materials such as glass, plastic, metal, flexible materials. Although not shown in the figure, various elements can be formed on the substrate (11). For example, the substrate (11) can be a thin film transistor substrate by disposing thin film transistors on the substrate (not shown in the figure), or the substrate (11) can be a thin film transistor substrate integrated with a color filter array (color filter on array, COA) by disposing thin film transistors (not shown in the figure) and a color filter layer (not shown in the figure) on the substrate (11), or the substrate (11) can be a thin film transistor substrate integrated with black matrix (black matrix on array, BOA) by disposing thin film transistors (not shown in the figure) and black matrix (not shown in the figure) on the substrate (11).

As shown in FIG. 1A, at least one OLED unit (12) is formed over the light emitting region (AA) of the substrate (11). Although not shown in the figure, the OLED unit (12) may comprise an upper electrode, a lower electrode, and an organic light emitting layer disposed between the upper electrode and the lower electrode. Moreover, the OLED unit (12) may optionally comprise an electron injection layer, an electron transport layer, a hole transport layer, a hole injection layer, and other layers that can help improve transportation and combination of electrons and holes.

As shown in FIG. 1B, the OLED unit (12) and the sealing region (B) of the substrate (11) are coated with an adhesive. The adhesive is then cured to be a protection layer (131) formed over the OLED unit (12) and a support unit (132) formed over the sealing region (B). In the present Embodiment, the adhesive can be a photo-curable resin or a thermo-curable resin, for example, acrylic resin or epoxy resin, but the disclosure is not limited to. In addition, in the present Embodiment, the method for coating the adhesive is not particularly limited. For example, the adhesive can be coated by a drip coating method using different molds/boards on the light emitting region (AA) and the sealing region (B), the adhesive can also be coated by jet printing or screen printing, to control the hydrophilicity and hydrophobicity of the surfaces of the elements which the protection layer (131) and the support unit (132) will be formed on later (which are the surface of the OLED unit (12) and the surface (11a) of the substrate); or to control the viscosity of the adhesive in the regions where the protection layer (131) and the support unit (132) are to be formed. However, the present disclosure is not limited thereto as long as a first height (H1) which is a maximum vertical distance between a surface (11a) of the substrate (11) and a surface (132a) of the support unit (132) departed from the surface (11a) of the substrate (11) is greater than a second height (H2) which is a maximum vertical distance between the surface (11a) of the substrate (11) and a surface (131a) of the protection layer (131) departed from the surface (11a) of the substrate (11).

As shown in FIG. 1C, a sealing unit (14) is formed on the support unit (132). The method for forming the sealing unit (14) is not particularly limited. For example, the sealing unit (14) can be formed by a glue dispensing method.

As shown in FIG. 1D, a cover (15) is disposed over the protection layer (131) and the support unit (132). The cover (15) connects to the support unit (132) by the sealing unit (14), so the sealing unit (14) is disposed between the cover (15) and the support unit (132). In the present Embodiment, the material of the cover (15) and the material of the substrate (11) can be the same or different. The materials of the cover (15) and the substrate (11) can be glass, plastic, flexible materials, etc. Furthermore, the cover could be a polarizer.

After completing the aforementioned steps, the display device of the present Embodiment is manufactured. As shown in FIG. 1D, the display device of the present Embodiment comprises: a substrate (11) having a light emitting region (AA) and a sealing region (B) surrounding the light emitting region (AA); an OLED unit (12) disposed over the light emitting region (AA); a protection layer (131) disposed over the OLED unit (12); a support unit (132) disposed over the sealing region (B), wherein materials of the protection layer (131) and the support unit (132) are the same, and the support unit (132) connects to the protection layer (131); and a cover (15) disposed over the protection layer (131) and the support unit (132) and the cover (15) connecting to a sealing unit (14); wherein a first height (H1) is a maximum vertical distance between a surface (132a) of the support unit (132) adjacent to the cover (15) and a surface (11a) of the substrate (11), and a second height (H2) is a maximum vertical distance between a surface (131a) of the protection layer (131) adjacent to the cover (15) and the surface (11a) of the substrate (11), and the first height (H1) is greater than the second height (H2).

There are always some particles adhered on the surface of the OLED unit (12) during the manufacturing process of the OLED unit (12). These particles may be pressed down onto the surface of the OLED unit (12) and damage the OLED unit (12) when the cover (15) is pressed and when there are no support unit (132) and protection layer (131). In the meantime, when devices are not encapsulated properly, external water vapor and oxygen can enter into the OLED unit (12) through damaged regions and affect the light-emitting efficiency and lifetime of the OLED unit (12). Accordingly, in the present Embodiment, an adhesive is applied on the surface of the OLED unit (12) and on the sealing region (B) of the substrate (11). The adhesive is then cured to form a protection layer (131) on the OLED unit (12) and a support unit (132) on the sealing region (B). A space (151) is also formed between the cover (15) and the protection layer (131) due to the second height (H2) is less than the first height (H1), wherein the first height (H1) is a maximum vertical distance between a surface (11a) of the substrate (11) and a surface (132a) of the support unit (132) away from the surface (11a) of the substrate (11), and the second height (H2) is a maximum vertical distance between the surface (11a) of the substrate (11) and a surface (131a) of the protection layer (131) away from the surface (11a) of the substrate (11). As a result, even when there are some particles adhered to the surface of the OLED unit (12), these particles would be embedded in the protection layer (131). Moreover, the space (151) can prevent the surface of the OLED unit (12) from being damaged by the particles adhered on the surface of the OLED unit (12) because the protection layer (131) could share the stress caused by pressing.

As shown in FIG. 1D, in the present Embodiment, the thickness (T2) of the protection layer (131) is smaller than the maximum thickness (T1) of the support unit (132). Consequently, the support unit (132) could bear the pressure when the cover (15) is disposed during the manufacturing process. Thereby, the damage of the OLED unit (12) can be improved.

As shown in FIG. 1D, in the present Embodiment, the protection layer (131) and integrated with the support unit (132). Thus, the manufacturing process is simpler, easier, and cheaper.

As shown in FIG. 1D, in the present Embodiment, the height (H3) of the space (151), which is between the cover (15) and the protection layer (131), may be between 1 μm and 5 mm in order to prevent the OLED unit (12) from being pressed when the cover (15) is pressed

As shown in FIG. 1D, in the present Embodiment, the width (W) of the support unit (132) may be between 0.1 mm and 10 mm in order to provide sufficient support.

### Embodiment 2

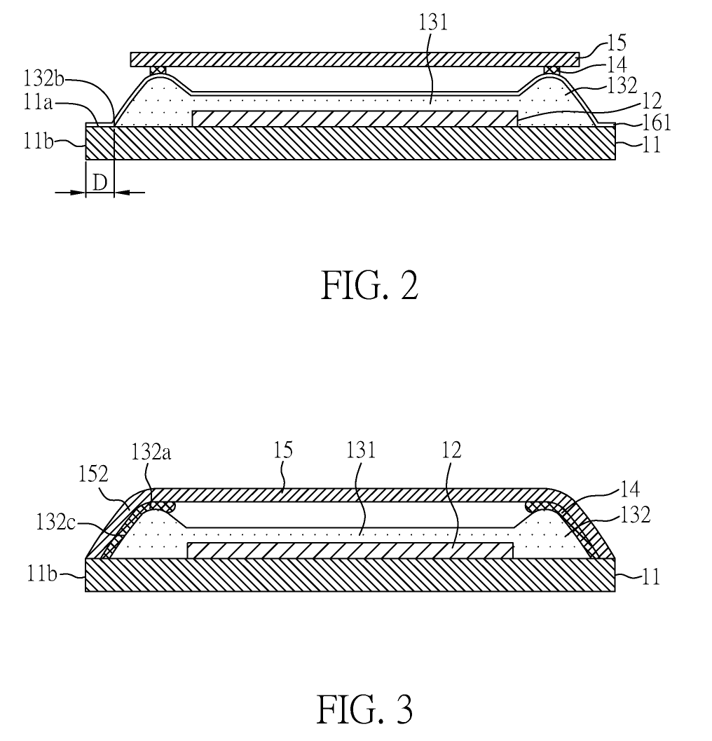

FIG. 2 is a cross-sectional view of a display device of the present Embodiment. The display device and the method for manufacturing the same of the present Embodiment is similar to that of Embodiment 1 except of the following.

In the present Embodiment, as shown in FIG. 2, after the formation of the protection layer (131) and the support unit (132) (as shown in FIG. 1B), a first barrier layer (161) is formed over the surface (131a) of the protection layer (131) and the surface (132a) of the support unit (132) (as shown in FIG. 1B). The sealing unit (14) is formed next and a cover (15) is disposed. Therefore, the display device of the present Embodiment further comprises: a first barrier layer (161) disposed over the surface of the protection layer (131) adjacent to the cover (15) and the surface of the support unit (132) adjacent to the cover (15). The first barrier layer (161) can further prevent the penetration of water vapor and oxygen into the OLED unit (12). The material of the first barrier layer (161) can be an inorganic layer or an inorganic/organic multilayer. Examples of the inorganic layer include, but not limited to, silicon nitride, silicon oxide, and diamond-like carbon.

There is a pre-determined distance (D) between an edge (132b) of the support unit (132) and an edge (11b) of the substrate (11) in a direction parallel to the substrate (11). The first barrier layer (161) is also disposed over partial of the surface (11a) of the substrate between the edge (132b) of the support unit (132) and the edge (11b) of the substrate (11). Thus, possibility of water vapor and oxygen penetrate into the device through the junction between the edge (132b) of the support unit (132) and the surface (11a) of the substrate (11) could be decreased. The possibility of the OLED unit (12) to deteriorate is further reduced.

### Embodiment 3

FIG. 3 is a cross-sectional view of a display device of the present Embodiment. The display device and the method for manufacturing the same of the present Embodiment are similar to that of Embodiment 1 except of the following.

In the present Embodiment, the cover (15) has an extended sidewall (152) and the extended sidewall (152) extends toward an edge (11b) of the substrate (11). Thus, the OLED unit (12), the protection layer (131), and the support unit (132) can be disposed in a space which is formed between the cover (15) and the substrate (11).

In addition, in the present Embodiment, the sealing unit (14) is not only disposed over the surface (132a) of the top of the support unit (132) as shown in Embodiment 1, but is also disposed over a sidewall (132c) of the support unit (132). Thus, the cover (15) and the support unit (132) are even more better sealed because the area of the sealing unit (14) of the present Embodiment is larger than that of Embodiment 1 and Embodiment 2. The penetration of water vapor and oxygen into the device is further prohibited.

### Embodiment 4

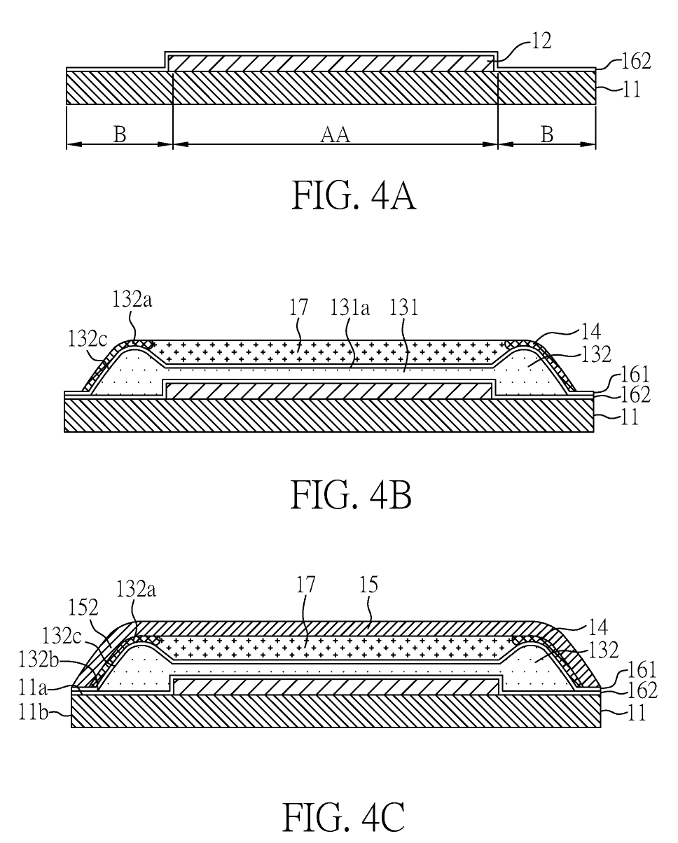

FIGS. 4A-4C are schematic diagrams showing a manufacturing process of a display device of the present Embodiment in cross-sectional view. The display device and the method for manufacturing the same of the present Embodiment is similar to that of Embodiment 1 except of the following.

As shown in FIG. 4A, after the formation of the OLED unit (12), a second barrier layer (162) is further formed on the OLED unit (12) and the sealing region (B).

As shown in FIG. 4B, after the formation of the protection layer (131) and the support unit (132), the first barrier layer (161) is further formed on the surface (131a) of the protection layer (131) and the surface (132a) of the support unit (132). The sealing unit (14) is then formed over the surface (132a) and the sidewall (132c) of the support unit (132). In more detail, the first barrier layer (161) could be disposed between the sidewall (132c) of the support unit (132) and the sealing unit (14). A filler unit (17) is then disposed over the protection layer (131). In more detail, the first barrier layer (161) could be disposed between the protection layer (131) and the filler unit (17).

Lastly, as shown in FIG. 4C, the cover (15) is disposed over the protection layer (131) and the support unit (132). The cover (15) connects to the support unit (132) by the sealing unit (14). After the filler unit (17) is cured, the manufacture of the display device of the present Embodiment is complete.

As shown in FIG. 4C, the display device of the present Embodiment is similar to that of Embodiment 3 except of the following. In the present Embodiment, the display device further comprises a first barrier layer (161) disposed over the surface of the protection layer (131) adjacent to the cover (15) and the surface of the support unit (132) adjacent to the cover (15). The first barrier layer (161) covers the sidewall (132c) of the support unit (132) as well as a region of the surface (11a) of the substrate (11) between the edge (132b) of the support unit (132) and the edge (11b) of the substrate (11) adjacent to the edge (132b) of the support unit (132). In addition, the display device of the present Embodiment further comprises: a second barrier layer (162) disposed between the OLED unit (12) and the protection layer (131). The second barrier layer (162) is further disposed between the support unit (132) and the substrate (11) as well as on a region of the surface (11a) of the substrate (11a) between the edge (132b) of the support unit (132) and the edge (11b) of the substrate (11) adjacent to the edge (132b) of the support unit (132).

Furthermore, in the display device of the present Embodiment, a filler unit (17) is disposed in a space between the cover (15) and the protection layer (131). The filler unit (17) can be used as a buffer layer as well as a support layer for supporting the cover (15) to prevent the OLED unit (12) from being damaged by deformation of the cover (15) when the cover (15) is pressed.

In the present Embodiment, the first barrier layer (161) and the second barrier layer (162) are the same as that of Example 2. Thus, the descriptions will not be repeated here again. The material of the filler unit (17) can be a photo-curable resin or a thermo-curable resin. The viscosity of the material of the filler unit (17) before curing is smaller than the viscosity of the material of the sealing unit (14) before curing. Other elements, such as scattering particles for increasing light extraction efficiency, can be added into the photo-curable resin or the thermo-curable resin of the filler unit (17) optionally to enhance the display quality of the display device.

### Embodiment 5

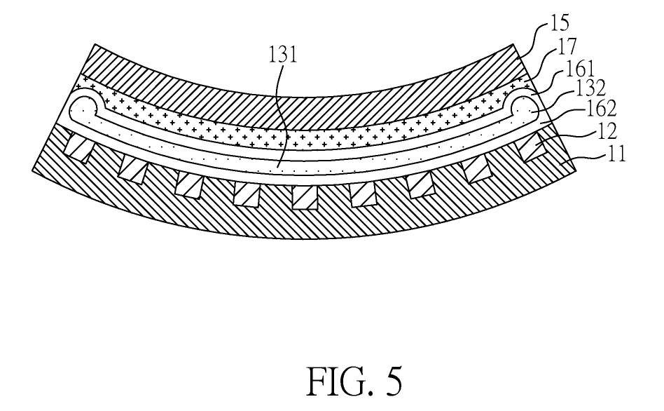

FIG. 5 is a cross-sectional view of a display device of the present Embodiment. The display device of the present Embodiment is similar to that of Embodiments 1-4 except that the present Embodiment provides a flexible display device comprising a plurality of OLED units (12) disposed over the light emitting region of the substrate (11). Please note that only one possible bending mode of the display device is shown in FIG. 5. However, the present disclosure is not limited thereto.

In the present disclosure, the display devices made in the aforesaid Embodiments can be used along with touch panels as touch display devices. In addition, the display devices or the touch display devices made in the aforesaid Embodiments of the present disclosure can be used in any electronic devices displaying images, such as monitors, mobile phones, laptop computers, video cameras, cameras, music players, mobile navigation systems, and televisions.

### Embodiment 6

The present Embodiment and Embodiments 1-5 all disclose light emitting devices. However, Embodiments 1-5 provide display devices and the present Embodiment provides a lamp. The structure of the lamp of the present Embodiment is similar to that of Embodiments 1-5 except of the following.

In the aforementioned Embodiments, thin film transistors are disposed on the substrates of the display devices provided, but there is no need to dispose such elements in the lamp of the present Embodiment. The OLED unit of the above embodiments could be replaced by an LED unit, ex. a micro LED unit.

Although the present disclosure has been explained in relation to its preferred examples, it is to be understood that many other possible modifications and variations can be made without departing from the spirit and scope of the disclosure as hereinafter claimed.

What is claimed is:

1. A light emitting device, comprising:
a substrate comprising a light emitting region and a sealing region surrounding the light emitting region;
an OLED unit disposed over the light emitting region;
a protection layer disposed over the OLED unit;
a support unit disposed over the sealing region, wherein materials of the protection layer and the support unit are the same, and the support unit connects to the protection layer; and
a cover disposed over the protection layer and the support unit;
wherein a first height is a maximum vertical distance between a surface of the support unit adjacent to the cover and a surface of the substrate, a second height is a maximum vertical distance between a surface of the protection layer adjacent to the cover and the surface of the substrate, and the first height is greater than the second height.

2. The light emitting device as claimed in claim 1, wherein a sealing unit is disposed between the cover and the support unit.

3. The light emitting device as claimed in claim 1, wherein a thickness of the protection layer is less than a maximum thickness of the support unit.

4. The light emitting device as claimed in claim 1, wherein the protection layer is integrated with the support unit.

5. The light emitting device as claimed in claim 1, further comprising a first barrier layer disposed over the surface of the protection layer adjacent to the cover and the surface of the support unit adjacent to the cover.

6. The light emitting device as claimed in claim 5, wherein the first barrier layer is further disposed over a region of the surface of the substrate between an edge of the support unit and an edge of the substrate adjacent to the edge of the support unit.

7. The light emitting device as claimed in claim 5, further comprising a second barrier layer disposed between the OLED unit and the protection layer.

8. The light emitting device as claimed in claim 7, wherein the second barrier layer is further disposed between the support unit and the substrate.

9. The light emitting device as claimed in claim 1, wherein the cover has an extended sidewall and the extended sidewall extends toward an edge of the substrate.

10. The light emitting device as claimed in claim 1, further comprising a filler unit disposed between the cover and the protection layer.

11. The light emitting device as claimed in claim 1, wherein the light emitting device is a display device or a lamp.

12. A method for manufacturing a light emitting device, comprising:
providing a substrate comprising a light emitting region and a sealing region surrounding the light emitting region;
forming an OLED unit over the light emitting region;
coating an adhesive over the OLED unit and the sealing region;
curing the adhesive to form a protection layer over the OLED unit and a support unit over the sealing region, wherein a first height is a maximum vertical distance between a surface of the support unit and a surface of the substrate, a second height is a maximum vertical distance between a surface of the protection layer and the surface of the substrate, and the first height is greater than the second height; and
disposing a cover over the protection layer and the support unit.

13. The method as claimed in claim 12, wherein a thickness of the protection layer is less than a maximum thickness of the support unit.

14. The method as claimed in claim 12, further comprising a step of forming a first barrier layer over the surface of the protection layer and the surface of the support unit after the adhesive is cured.

15. The method as claimed in claim 12, further comprising a step of forming a sealing unit over the support unit before disposing the cover on the protection layer, in which the cover connects to the support unit by the sealing unit.

16. The method as claimed in claim 14, further comprising a step of forming a second barrier layer between the OLED unit and the adhesive after the OLED unit is formed.

17. The method as claimed in claim 12, wherein the cover has an extended sidewall and the extended sidewall extends toward an edge of the substrate.

18. The method as claimed in claim 12, further comprising steps of disposing a filler unit over the protection layer before disposing the cover on the protection layer and the support unit; and curing the filler unit after disposing the cover over the protection layer and the support unit.

19. The method as claimed in claim 12, wherein the light emitting device is a display device or a lamp.
